(19) United States
(12) Patent Application Publication
(10) Pub. No.: US 2007/0254137 A1
(43) Pub. Date: Nov. 1, 2007

(54) Thermally Conducting Multi-Layer Film

(75) Inventors: Franz Koppe, Eschenbach/Opf. (DE); Werner Haas, Pegnitz (DE)

Correspondence Address: MERCHANT & GOULD PC, P.O. BOX 2903, MINNEAPOLIS, MN, 55402-0903, US

(73) Assignee: KERAFOL KERAMISCHE FOLIEN GMBH, ESCHENBACH (DE)

(21) Appl. No.: 11/660,426

(22) PCT Filed: Jul. 13, 2005
(86) PCT No.: PCT/DE05/01234

§ 371 Date: Feb. 13, 2007

(30) Foreign Application Priority Data
Aug. 13, 2004 (DE) 10 2004 039 565.9

(51) Int. Cl. B32B 27/40; B32B 7/02; C09K 5/06; G11C 11/00

(52) U.S. Cl. 428/141

(57) ABSTRACT

A thermally conducting multi-layer film which includes of a first layer configured by an electrically insulating, thermally conducting, filled in, highly elastic elastomer layer which due to its gel characteristics can be permanently molded onto the uneven surface structure of an electronic circuit, and at least one second layer which is considerably thinner than the first layer and firmly linked therewith. The second layer is configured as a PCM layer which is applied to the first layer and thins out and/or brings about a change of state under the influence of pressure and/or temperature when a cooling body or housing element is applied.

The invention relates to a thermally conducting multi-layer film that consists of a first layer, which is formed through an electrically insulating, thermally conducting, filled, and highly elastic elastomer layer. Due to its gel characteristics, this layer is capable of being permanently molded onto the uneven surface structure of an electronic circuit. In addition, the thermally conducting film displays at least one second layer, which is substantially thinner than the first layer and is firmly connected to the latter.

Known thermally conducting multi-layer films are generally used for the purpose of drawing heat away from uneven structures that contain or consist of thermally sensitive electronic components. Such films are available with a thickness of 0.5-5 mm, exhibit a thermal resistance of between 0.25 and 1.75 K/W, and ensure a thermal conductivity in the range of 0.8 to 5 W/mK. The thermal application region of such thermally conducting films, which are also called gap-filler films, lies in the range of −60 to +200° C. Such gap-filler materials are described, for example, in the product overview of the firm Kerafol Keramische Folien GmbH, Eschenbach, and are designated there as the product “Soft-therm”.

Disadvantageous in all such known thermally conducting films is a substrate, which as a rule displays a thickness of approximately 0.1 cm. This substrate has a relatively high heat-resistance value, so that the heat conduction in a housing element, heat sink, etc. that is attached thereto is limited.

The invention/innovation is based on the task of further developing a multi-layer thermally conducting film with the features of the preamble of claim 1 in such a way that an improved dissipation from the highly elastic elastomer layer with gel characteristics is ensured. According to the invention, this task is accomplished through the fact that the second layer is formed as a PCM layer applied to the first layer, which PCM layer, with the application of a heat sink or housing element, thins out and/or brings about a change in its state of aggregation under the influence of pressure and/or temperature.

In principle, such PCM layers are known in themselves, but the combination of the two described layers has proved to be new and advantageous for accomplishing the task, in which combination the heat-resistance increasing substrate is eliminated and the PCM layer is directly applied to the elastomer layer. Tests have shown that the heat-resistance value is improved by a factor of 2 to 10 when the second layer is embodied not as a substrate but rather as a PCM layer.

Further developments of the invention are the result of the dependent claims 2-20. Thus, for example, the first layer can contain silicone or consist of a silicone-free, elastomeric, aliphatic polyurethane, where the polyurethane can be free of uncombined isocyanate groups. It is also possible to allow the first layer to consist of polydimethylsiloxane, where the polyurethane or the polydimethylsiloxane is filled at 50-95% with powder-form fill materials. The filling can consist of aluminum oxide particles, silicon oxide particles, beryllium oxide particles, magnesium oxide particles, aluminum nitride particles, boron nitride particles, silicon nitride particles, silicon carbide particles, or metallic particles.

For stabilization, the first layer can be mixed with a content of 0.5-15% of a melamine resin. The Shore hardness of the first layer amounts to 5-80, and 0.3-6 mm has proved to be the advantageous thickness range.

The second layer should consist of a waxy substance or at least contain such a substance. However, it is also possible to provide a copolymer as the second layer. The second layer can also consist of a thermoplastic silicone polymer or contain such a polymer. In the temperature range of 40° C.-140° C. a solid/fluid phase transition of the PCM layer forming the second layer is provided. The material of the second layer can likewise be filled with thermally conductive materials. The material of the first and/or second layer can be provided with a reinforcement consisting of, for example, metals or plastics, fiberglass, carbon, or graphite. The reinforcement of the first or second layer can also be formed in the manner of a textile. Finally, it is advantageous to provide the open surfaces of the first and/or second layer with an adhesive layer. For storage, it is further advantageous to apply to the open surfaces of the first and/or second layer a removable protective layer.

The invention is illustrated in detail with the aid of an advantageous embodiment example in the drawings. In the drawings:

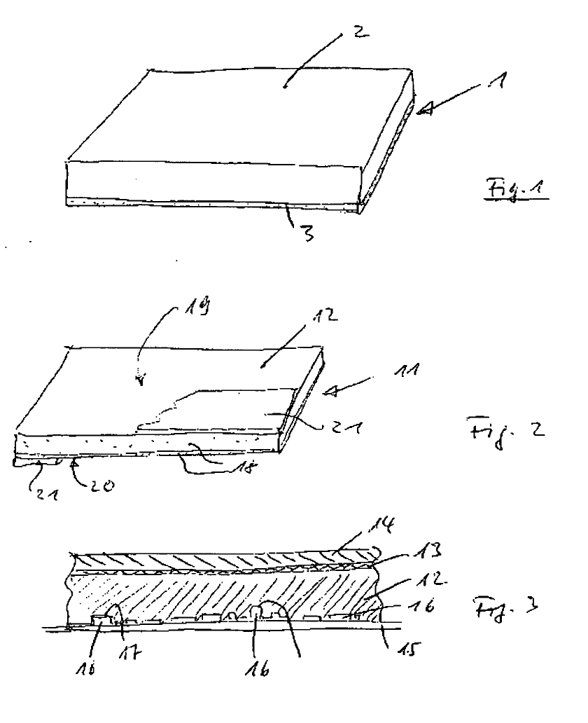

FIG. 1 shows a thermally conducting multi-layer film according to the prior art, in which the second layer is formed as a thin substrate.

FIG. 2 shows a thermally conducting multi-layer film according to the invention.

FIG. 3 shows a section through a printed circuit board provided with electronic components, onto which board is applied the thermally conducting multi-layer film according to the invention, which, on the side opposite to the printed circuit board, adjoins a housing element or a heat sink surface.

The thermally conducting multi-layer film 1 according to the prior art represented in FIG. 1 consists, in essence, of a first layer 2 and a second layer 3 that directly adjoins and is applied to the first layer 2, the second layer being substantially thinner than the first layer 1. Between the two layers 2 and 3 there exists a firm connection.

In the thermally conducting film 1 known from the prior art, which is represented in a schematic manner, the first layer 2 consists of an electrically insulating, thermally conducting, filled, and highly elastic elastomer layer with gel characteristics, and the second layer is a substrate that, in general, serves to stabilize the first layer 2.

In the thermally conducting film 11 according to the invention, the first layer 12 is formed in a manner corresponding to the first layer 2 of the thermally conducting film represented in FIG. 1; however, the substrate 3 is no longer present, but rather a second layer adjoins directly to a surface of the first layer 12, which second layer, upon application of a heat sink or housing element 14 (FIG. 3), thins out and/or brings about a change in its state of aggregation under the influence of pressure and/or temperature. Through this means, there comes about a very intensive thermal contact between the first layer and the housing element 14. Represented schematically in FIG. 3 is, in addition, a printed circuit board 15, attached to which are the electronic components 16 that are more or less tightly surrounded by the dents or impressions 17 in the first layer 12, so that a good thermal dissipation from the components 16 into the first layer 12 of the thermally conducting film 11 is ensured.

It is possible to provide the material of the first layer 12 or the second layer 13 with reinforcement particles 18 or to insert a textile-like reinforcement, which is not illustrated in detail.

The open surfaces 19 and/or 20 of the first and/or second layers 12, 13 can be provided with a removable protective layer 21, which in the drawings is shown only in a regional manner.

1. Thermally conducting multi-layer film, comprising a first layer, which is formed by an electrically insulating, thermally conducting, filled, and highly elastic elastomer layer, which in consequence of its gel characteristics can be permanently molded onto the uneven surface structure of an electronic circuit, and at least one second layer, which is substantially thinner than the first layer and is firmly connected to the latter, wherein the second layer is formed as a PCM layer that is applied to the first layer, which PCM layer, with the application of a heat sink or housing element, thins out and/or brings about a change in its state of aggregation under the influence of pressure and/or temperature.

2. Thermally conducting film according to claim 1, wherein the first layer contains silicone.

3. Thermally conducting film according to claim 1, wherein the first layer comprises a silicone-free, elastomeric, aliphatic polyurethane.

4. Thermally conducting film according to claim 3, wherein the polyurethane is free of uncombined isocyanate groups.

5. Thermally conducting film according to claim 1, wherein the first layer comprises polydimethylsiloxane.

6. Thermally conducting film according to claim 1, wherein the polyurethane or polydimethylsiloxane is filled at 50-95% with powder-form fill materials.

7. Thermally conducting film according to claim 1, wherein the filling is selected from the grouping consisting of aluminum oxide particles, silicon oxide particles, beryllium oxide particles, magnesium oxide particles, aluminum nitride particles, boron nitride particles, silicon nitride particles, metallic particles, and/or silicon carbide particles.

8. Thermally conducting film according to claim 1, wherein the first layer is mixed with a content of 0.5-15% of a melamine resin.

9. Thermally conducting film according to claim 1, wherein the Shore hardness of the first layer is in the range of 5 to 80.

10. Thermally conducting film according to claim 1, wherein the thickness of the first layer is in the range of 0.3 to 6 mm.

11. Thermally conducting film according to claim 1, wherein the second layer comprises a waxy substance or contains a waxy substance.

12. Thermally conducting film according to claim 1, wherein the second layer comprises a copolymer or contains a copolymer.

13. Thermally conducting film according to one claim 1, wherein the second layer comprises a thermoplastic silicone polymer or contains a thermoplastic silicone polymer.

14. Thermally conducting film according to claim 1, wherein the PCM layer forming the second layer has a solid/fluid phase transition in the temperature interval of 40° C.-140° C.

15. Thermally conducting film according to claim 1, wherein the material of the second layer is filled with thermally conductive materials.

16. Thermally conducting film according to claim 1, wherein the material of the first layer and/or the second layer is provided with a reinforcement.

17. Thermally conducting film according to claim 16, wherein the reinforcement is selected from the group consisting of metallic materials or plastics, fiberglass, carbon, or graphite.

18. Thermally conducting film according to claim 1, wherein the first layer and/or the second layer is provided with a textile-like reinforcement.

19. Thermally conducting film according to claim 1, wherein the open surfaces of the first layer and/or the second layer are provided with an adhesive layer.

20. Thermally conducting film according to claim 1, wherein the open surfaces of the first layer and/or the second layer are provided with a removable protective layer.
